(19) United States
(12) Patent Application Publication
(10) Pub. No.: US 2024/0427409 A1
(43) Pub. Date: Dec. 26, 2024

(54) ELECTRICAL DEVICE WITH A DEEP SLEEP MODE IMPLEMENTED WITH A LEVEL SHIFTER

(71) Applicant: QUALCOMM Incorporated, San Diego, CA (US)

(72) Inventors: Yue LU, Santa Clara, CA (US); Jin-Su KO, San Jose, CA (US); Thinh NGUYEN, San Jose, CA (US); Jun ZHAO, San Ramon, CA (US)

(21) Appl. No.: 18/338,165

(22) Filed: Jun. 20, 2023

(51) Int. Cl. G06F 1/3287; G06F 1/3296

(52) U.S. Cl. CPC G06F 1/3287; G06F 1/3296

(57) ABSTRACT

Certain aspects of the present disclosure are directed towards an apparatus for power management. The apparatus generally includes a switch and logic configured to: receive an input to configure the apparatus in a deep sleep mode; and open the switch to turn off power from a voltage rail to at least one first circuit having leakage current that is greater than a threshold, wherein at least one second circuit having leakage current less than the threshold is coupled to the voltage rail.

### TECHNICAL FIELD

Certain aspects of the present disclosure generally relate to electronic circuits, and more particularly, to power management for an electronic device.

### BACKGROUND

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. An electronic device like a smartphone may depend on a battery to operate. The life of the battery may be dependent on the power consumption of circuitry on the electronic device. Some circuitry, such as a low dropout (LDO) regulator, may consume power even when inactive.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects are directed towards an apparatus for power management. The apparatus generally includes a switch and logic configured to: receive an input to configure the apparatus in a deep sleep mode; and in response to the received input, open the switch to turn off power from a voltage rail to at least one first circuit having a leakage current that is greater than a threshold, wherein at least one second circuit having a leakage current less than the threshold is coupled to the voltage rail.

Certain aspects are directed towards a level shifter. The level shifter generally includes: a pair of cross-coupled transistors; a first pair of cascode transistors coupled in cascode to the pair of cross-coupled transistors, respectively; a first diode coupled between a gate and a source of a first transistor of the first pair of cascode transistors; a second diode coupled between a gate and a source of a second transistor of the first pair of cascode transistors; and a pair of input transistors having drains coupled to drains of the first pair of cascode transistors, respectively.

Certain aspects are directed towards a method for power management. The method generally includes: receiving an input to configure an apparatus in a deep sleep mode; and opening a switch to turn off power from a voltage rail to at least one first circuit having a leakage current that is greater than a threshold, wherein at least one second circuit having a leakage current less than the threshold is coupled to the voltage rail.

Certain aspects are directed towards an apparatus for power management. The apparatus generally includes: a low-dropout (LDO) regulator; a headswitch coupled between a voltage rail and a power supply node of the LDO regulator; a level shifter configured to control a state of the headswitch, and logic coupled to the level shifter and configured to control the level shifter based on a first sleep state, a second sleep state, and a third state of the apparatus.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates a wireless communications system with access points and user terminals, in which aspects of the present disclosure may be practiced.

FIG. 2 shows a block diagram of an access point and user terminals, in which aspects of the present disclosure may be practiced.

FIG. 3 is a block diagram of an example transceiver front end, in which aspects of the present disclosure may be practiced.

FIG. 4 illustrates different modes of an example front-end module (FEM) including a deep sleep mode, in accordance with certain aspects of the present disclosure.

FIG. 5 is a block diagram illustrating example power management circuitry capable of activating a deep sleep mode, in accordance with certain aspects of the present disclosure.

FIG. 6 is a block diagram illustrating example power management circuitry capable of activating a deep sleep mode with register retention, in accordance with certain aspects of the present disclosure.

FIG. 7 is a graph illustrating example bias points for a transistor.

FIGS. 8A and 8B illustrate example level shifters, in accordance with certain aspects of the present disclosure.

FIG. 9 is a flow diagram illustrating example operations for power management, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to techniques and apparatus for power management. For example, certain aspects provide techniques for configuring an electric device in a sleep mode during which one or more circuits are configured in low-power mode, or in a deep sleep mode where power to the one or more circuits is turned off by opening a switch. For example, the switch may be a head switch coupled between the one or more circuits and a voltage rail. Status information associated with the one or more circuits (e.g., a digital low dropout (LDO) regulator) may be stored in one or more registers to be used when reactivating the one or more circuits. In some aspects, a level shifter may be used to control the switch.

In some implementations, one or more transistors of a level shifter may have a negative source-to-gate voltage (Vsg), resulting in an overvoltage condition for other transistors of the level shifter (or a transistor used to implement the head switch for the deep sleep mode), causing reliability issues. The negative Vsg may be caused by gate-induced drain leakage (GIDL). In some aspects of the present disclosure, the level shifter may be implemented with diodes so that the Vsg of the transistors of the level shifter do not operate with a negative Vsg, increasing the reliability of the level shifter, the switch, or the electric device including the level shifter.

### Example Wireless Communications

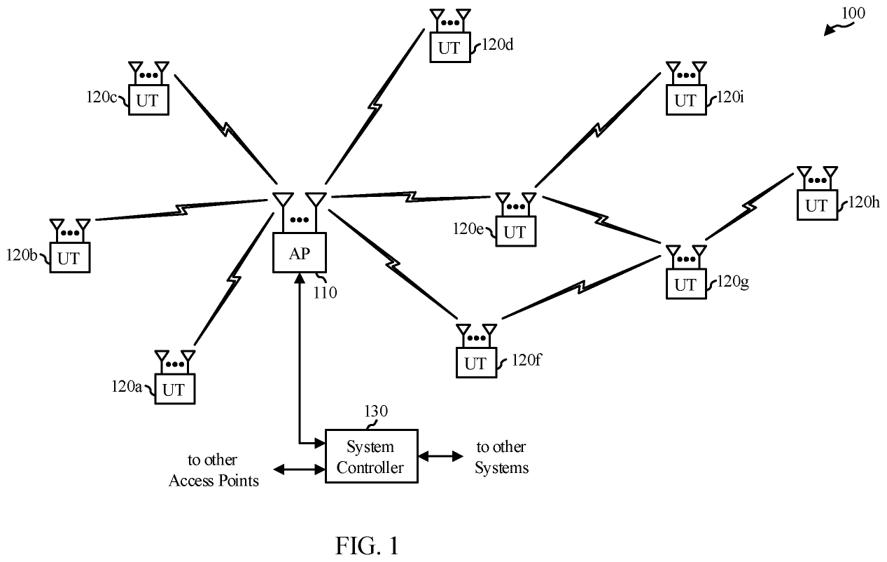

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), a next generation Node B (gNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be supported).

In some aspects, the user terminal 120 or access point 110 may be placed in a deep sleep mode by opening a switch to turn off power to one or more circuits. The switch may be controlled via a level shifter, as described in more detail herein.

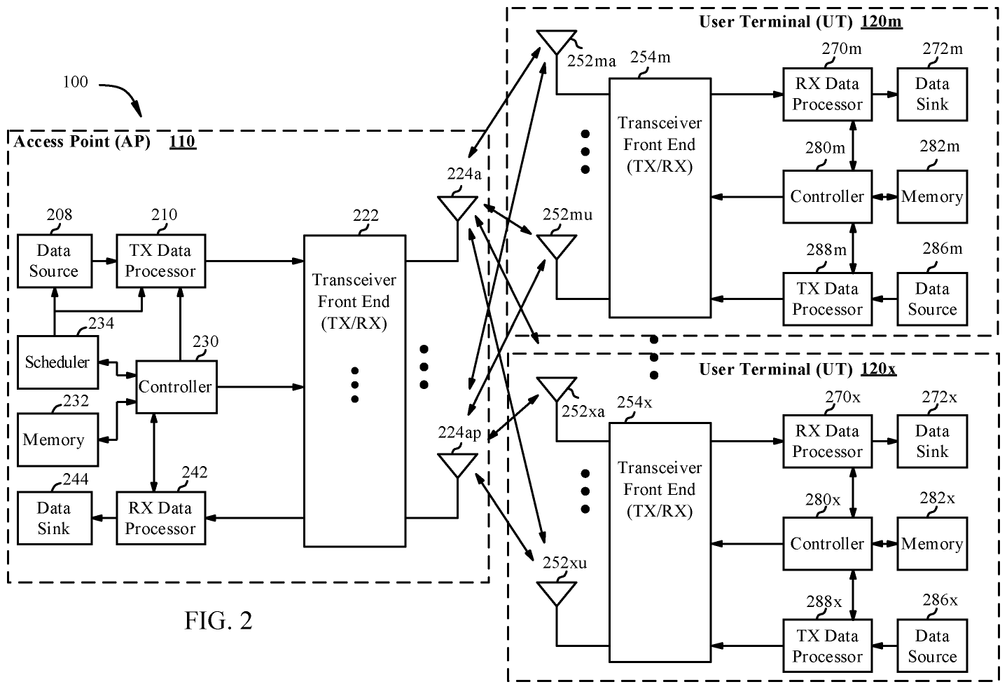

FIG. 2 shows a block diagram of access point 110 and two user terminals 120m and 120x in the wireless communications system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink. Nᵤₚ may or may not be equal to N_{dn}, and Nᵤₚ and N_{dn} may be static values or can change for each scheduling interval. Beam-steering, beamforming, or some other spatial processing technique may be used at the access point and/or user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110. Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one or more of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal (e.g., which may be provided to a data sink 272).

In some aspects, the user terminal 120 or access point 110 may be placed in a deep sleep mode by opening a switch to turn off power to one or more circuits. The switch may be controlled via a level shifter, as described in more detail herein.

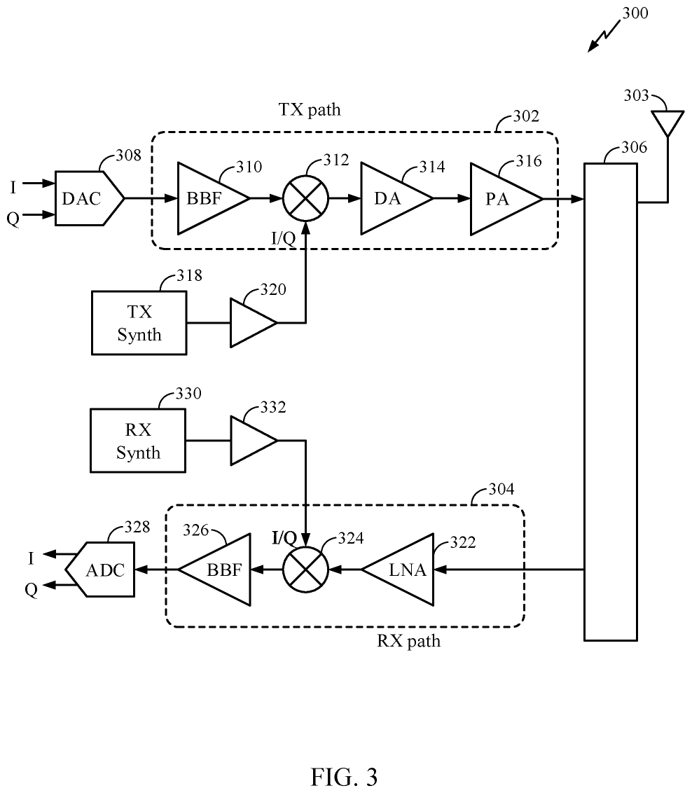

FIG. 3 is a block diagram of an example transceiver front end 300, such as transceiver front ends 222, 254 in FIG. 2, in which aspects of the present disclosure may be practiced. The transceiver front end 300 includes at least one transmit (TX) path 302 (also known as a “transmit chain”) for transmitting signals via one or more antennas and at least one receive (RX) path 304 (also known as a “receive chain”) for receiving signals via the antennas. When the TX path 302 and the RX path 304 share an antenna 303, the paths may be connected with the antenna via an interface 306, which may include any of various suitable radio frequency (RF) devices, such as a switch, a duplexer, a diplexer, a multiplexer, and the like.

Receiving in-phase (I) and/or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, the DA 314, and the PA 316 may be included in a radio frequency integrated circuit (RFIC). In some cases, the PA 316 may be external to the RFIC.

The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 312 are typically RF signals, which may be amplified by the DA 314 and/or by the PA 316 before transmission by the antenna 303. While one mixer 312 is illustrated, several mixers may be used to upconvert the filtered baseband signals to one or more intermediate frequencies and to thereafter upconvert the intermediate frequency (IF) signals to a frequency for transmission.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO frequency may be produced by a TX frequency synthesizer 318, which may be buffered or amplified by amplifier 320 before being mixed with the baseband signals in the mixer 312. Similarly, the receive LO frequency may be produced by an RX frequency synthesizer 330, which may be buffered or amplified by amplifier 332 before being mixed with the RF signals in the mixer 324. In some cases, a single frequency synthesizer may be used for both the TX path 302 and the RX path 304.

In some aspects, a wireless device (e.g., the user terminal 120 or access point 110) may be placed in a deep sleep mode by opening a switch to turn off power to one or more circuits for the transceiver front end 300. The switch may be controlled via a level shifter, as described in more detail herein.

While FIGS. 1-3 describe an example configuration of a wireless communication system to facilitate understanding, the aspects of the present disclosure may be applied to any suitable electronic system or wireless communication system. For example, a wireless communication system may be implemented with a modem integrated circuit (IC), a transceiver IC, and a front-end module. The modem IC may be part of a main system-on-chip (SoC) with an application processor, in some aspects. The modem IC may be coupled to the transceiver IC (e.g., a separate wireless local area network (WLAN) chip or a separate sub-6 GHz software-defined radio (SDR) chip). The transceiver IC may include baseband circuitry, mixers, and pre-amplifiers. The transceiver IC may be coupled to the front-end module including a PA. Certain aspects of the present disclosure may be used to reduce current consumption associated with any components of the wireless communication system (e.g., components of the transceiver IC or the front-end module).

### Example Techniques for Deep Sleep Mode

In some implementations, a front-end module (FEM) may be configured in a standby mode to reduce power consumption. During the standby mode (e.g., also referred to as a sleep mode), the current consumption of the FEM may be reduced (e.g., to as low as 10 μA). Certain aspects of the present disclosure are directed towards implementing a deep sleep mode where the current consumption of the FEM may be further reduced (e.g., down to 1 μA). For example, a head switch (or tail switch) may be used to turn off power to specific circuits that would otherwise have a leakage current above a threshold. As used herein, leakage current generally refers to the current consumption of a circuit when the circuit is inactive. For example, a low dropout (LDO) regulator may be inactive (e.g., may not be generating a regulated voltage output), but may still consume power due to the leakage current of devices (e.g., transistors) used to implement the LDO regulator. In some aspects of the present disclosure, a switch may be opened to turn off power to circuits with a leakage current above a certain threshold.

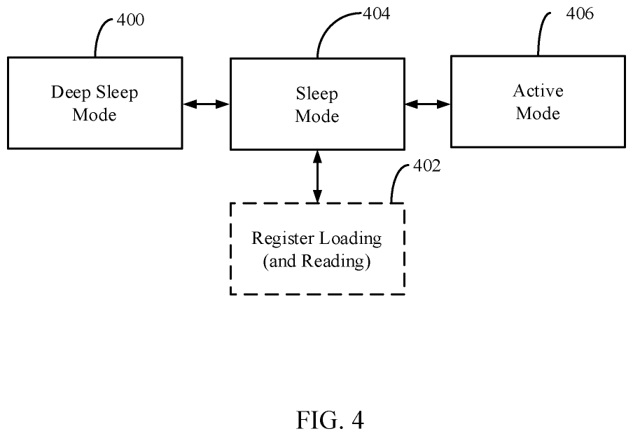

FIG. 4 illustrates different modes of a FEM including a deep sleep mode, in accordance with certain aspects of the present disclosure. As shown, the FEM may operate in an active mode 406 (e.g., for data reception or transmission). In some cases, the FEM may be placed in a sleep mode 404 where certain circuits of the FEM may be placed in a low-power mode of operation (e.g., a low-current mode). For example, one or more oscillators, charge pump circuitry, power amplifier (PA), low-noise amplifier (LNA) (e.g., LNA 322 of FIG. 3), digital input/output (DIO) circuitry, and/or electronic fuse (efuse) circuitry (e.g., for storing default settings associated with the FEM) may be placed in a low-power mode of operation (e.g., deactivated).

In certain aspects of the present disclosure, the FEM may be placed in a deep sleep mode 400 where current consumption may be reduced further than in sleep mode. In deep sleep mode, a head switch or tail switch may be used to turn off power to one or more circuits that have leakage currents that are greater than some threshold. The one or more circuits may be identified (e.g., via testing) to have leakage currents greater than the threshold. For example, the head switch or tail switch may be used to turn off power to any circuit that has a leakage current greater than 1 μA. For instance, in deep sleep mode, power may additionally be turned off to one or more low dropout (LDO) regulators for digital or analog circuitry or bandgap (BG) voltage generation circuitry. As used herein, a head switch may refer to a switch coupled between a circuit to be powered and a positive voltage rail (e.g., a positive power supply node), whereas a tail switch may refer to a switch coupled between the circuit and a reference potential node (e.g., electrical ground) or a negative voltage rail (e.g., a negative power supply node). While some examples provided herein are described with respect to a head switch to facilitate understanding, the aspects of the present disclosure may be implemented with a tail switch in a similar manner.

In some aspects, prior to turning off power to one or more circuits, status information associated with the one or more circuits may be stored in registers at block 402. By storing the status information before entering deep sleep mode 400 and reading this information upon exiting from the deep sleep mode, the one or more circuits may be directly configured with a setting the one or more circuits had prior to entering the sleep or deep sleep mode.

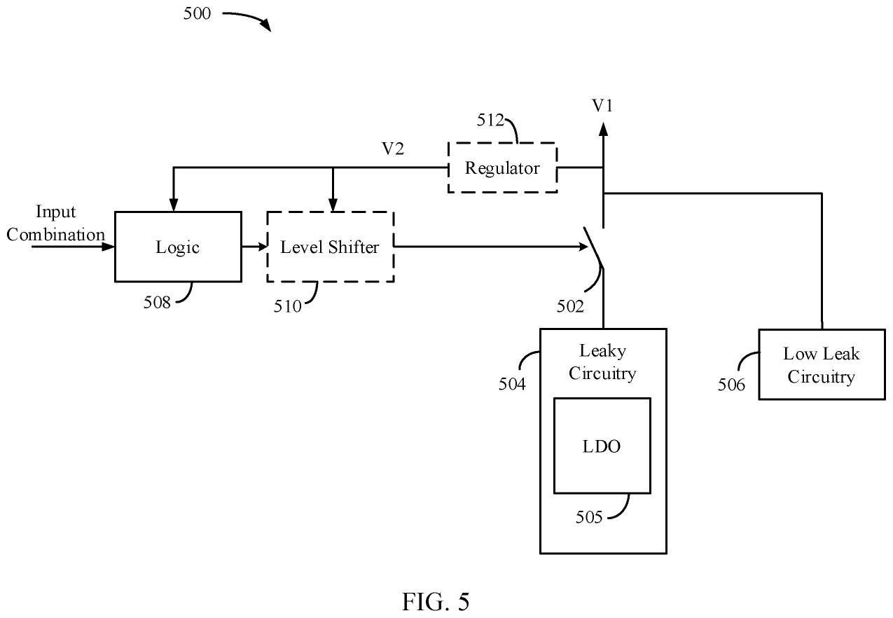

FIG. 5 is a block diagram illustrating power management circuitry 500 for activating a deep sleep mode, in accordance with certain aspects of the present disclosure. As shown, the power management circuitry 500 may include a head switch 502 that may be coupled between a voltage rail (labeled “V1”) and leaky circuitry 504. The head switch 502 may be implemented by a low leakage current transistor. Leaky circuitry 504 may refer to one or more circuits that have a leakage current that is above a threshold (e.g., 1 μA). For example, the leaky circuitry 504 may include an LDO regulator 505.

As shown, the voltage rail V1 may also be provided to low leakage circuitry 506. The low leakage circuitry may include circuitry with a leakage current lower than a threshold (e.g., 1 μA). For example, the low leakage circuitry 506 may include a PA, such as the PA 316 of FIG. 3. In other words, when deactivated, the PA 316 may consume little current (e.g., less than 1 μA), and thus, may be operated directly from the voltage rail V1 (e.g., as opposed to operating from voltage rail V1 through a head switch). Moreover, due to the high power consumption of the PA 316 when active, the PA 316 may be adversely impacted by the on-resistance of the head switch 502. Thus, the PA 316 (and/or other circuits with similar characteristics or concerns) may be directly coupled to the voltage rail V1 so that the current from the voltage rail V1 to the PA 316 does not pass through the head switch 502.

As shown, the power management circuitry 500 may include logic 508 for controlling the head switch 502. The logic 508 may include any suitable controller or processors configured to control the head switch 502. In some cases, the logic 508 may include a logical not-OR (NOR) gate, as described in more detail herein. In some aspects, the logic 508 may control the head switch 502 through a level shifter 510, as described in more detail herein. In some aspects, the logic 508 may receive an input combination (e.g., a digital input of 0000 as described below), in response to which, the logic 508 may output a logic high to open the head switch 502 and activate the deep sleep mode. In certain aspects, the logic 508 may operate from a voltage rail (V2). The voltage at the rail V2 may be generated based on the voltage at the rail V1 via a regulator 512, in some aspects.

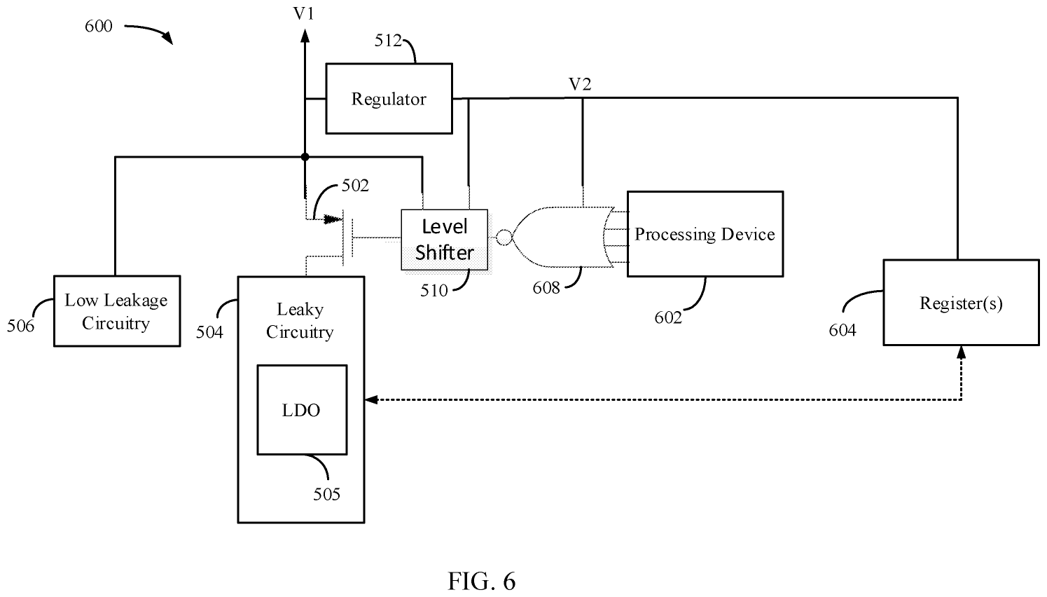

FIG. 6 is a block diagram illustrating power management circuitry 600 for activating a deep sleep mode with register retention, in accordance with certain aspects of the present disclosure. As shown, the power management circuitry 600 may include one or more registers 604 that may be used to retain status information associated with the leaky circuitry 504 to which power may be turned off via the head switch 502 during deep sleep mode. As shown, power to the one or more registers 604 may remain on even when the switch 502 is opened. In some aspects, the one or more registers 604 may operate using the voltage rail V2.

Prior to deep sleep mode, status information associated with the leaky circuitry 504 (or low leakage circuitry 506) may be stored in the one or more registers 604. The status information may be used to reactivate the circuitry. For example, the status information may be stored for power-on reset (POR) circuitry, low dropout (LDO) regulators, and/or other digital circuits. In some aspects, status information associated with oscillator(s) and/or efuse data may be stored in the one or more registers 604. In some aspects, the information stored in registers prior to entering deep sleep mode may include, for example, LDO settings, one or more gain values for a receiver, or one or more power levels for a transmitter. Using the stored information, when exiting the deep sleep mode (to sleep mode and eventually to active mode), transceiver/front-end circuitry may be reactivated and directly configured back to a previous setting (e.g., back to the setting the system was in prior to entering sleep mode or deep sleep mode).

In some aspects, the FEM may first transition from deep sleep mode to sleep mode before transitioning to active mode. Sleep mode (e.g., standby mode) may take time to settle (e.g., associated with the settling time of BG voltage generation and LDO) upon existing deep sleep mode. To shorten the transition time from deep sleep mode to sleep mode (e.g., and finally to active mode), leaky circuitry 504 may use fast charging with high current consumption (e.g., a few mA) at a beginning phase of sleep mode and subsequently operate with normal current consumption (e.g., 10 μA) to reduce standby current during the remaining time in sleep mode.

As shown, the logic 508 may be implemented using a NOR gate 608. For example, if the NOR gate receives (e.g., from a processing device 602) an input combination of 0000, the NOR gate may output a logic high to a level shifter 510. With any other digital input combination, the NOR gate may output a logic low. The level shifter 510 may be used to drive the head switch 502. The head switch 502 may be implemented as a p-type metal-oxide-semiconductor (PMOS) transistor, which may be turned off to cut off power to the leaky circuitry 504 during deep sleep mode as described.

### Example Level Shifter Circuit

Operating a switch (e.g., head switch 502) with low leakage using a level shifter (e.g., level shifter 510) may result in two bi-stable bias points for a PMOS transistor used to implement the level shifter and the switch. The two bi-stable bias points may be caused by gate-induced drain leakage (GIDL). Thus, the PMOS transistor may operate with a source-to-gate voltage (Vsg) of zero volts at a low source-to-drain current (Isd) or a negative Vsg (e.g., −2.5 V). When operating with a negative Vsg, certain reliability issues may arise for other components coupled to the PMOS transistor, as described in more detail herein.

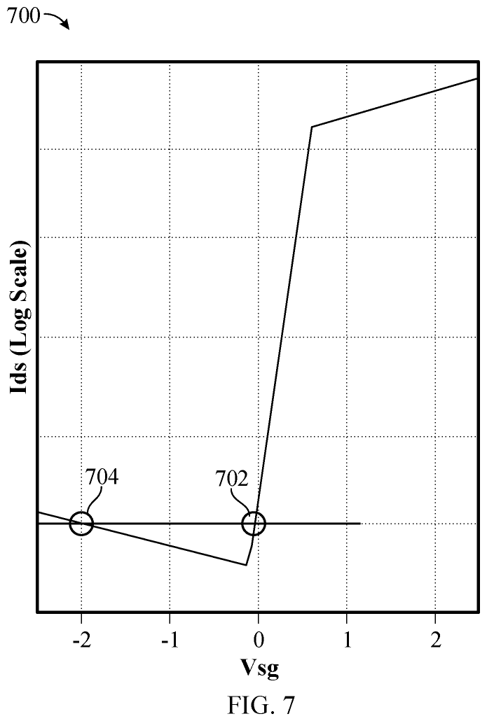

FIG. 7 is a graph 700 illustrating two bias points 702, 704 for a PMOS transistor operating with low Ids. As shown, at low Ids (transistor off mode), bias point 702 may occur at nearly zero Vsg, or bias point 704 may occur at a negative Vsg. If the PMOS transistor operates with a negative Vsg, reliability issues may arise for other devices (e.g., other PMOS and NMOS transistors used to implement the level shifter and head switch) or the life cycle of the other devices may be shortened (e.g., shortening product life cycle). For example, head switch 502 may be implemented as an extended drain device that can handle a large drain-to-source voltage (Vds) (e.g., may be able to handle a Vds of 5V). However, the head switch 502 may have a thin gate oxide layer. As a result, the head switch 502 may be unable to handle a large Vsg (e.g., may be unable to handle a Vsg greater than 3 V). In other words, the PMOS transistor used to implement switch 502 may have a Vsg capability of 3 V (e.g., a maximum Vsg capability of 3 V). If the PMOS transistor operates with a negative Vsg, a large voltage differential may be applied between the source and gate of the PMOS transistor used to implement the head switch, causing reliability issues or a shortened life cycle.

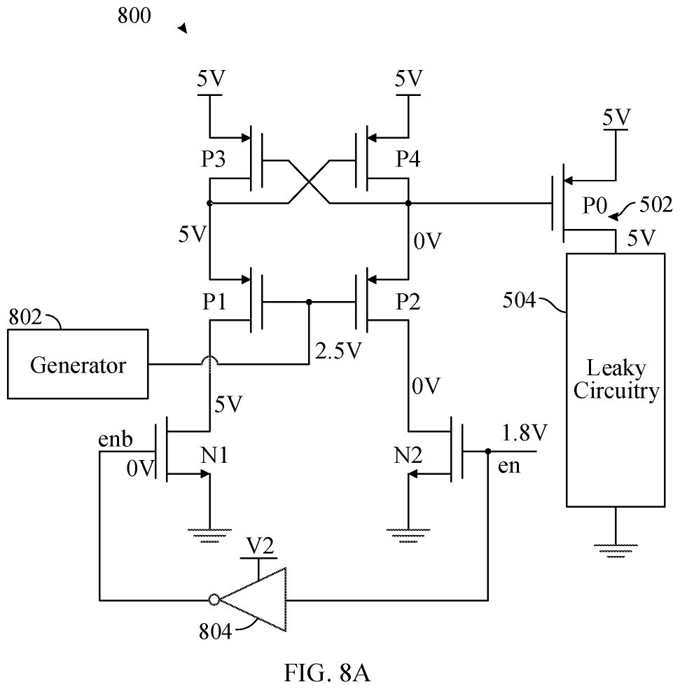

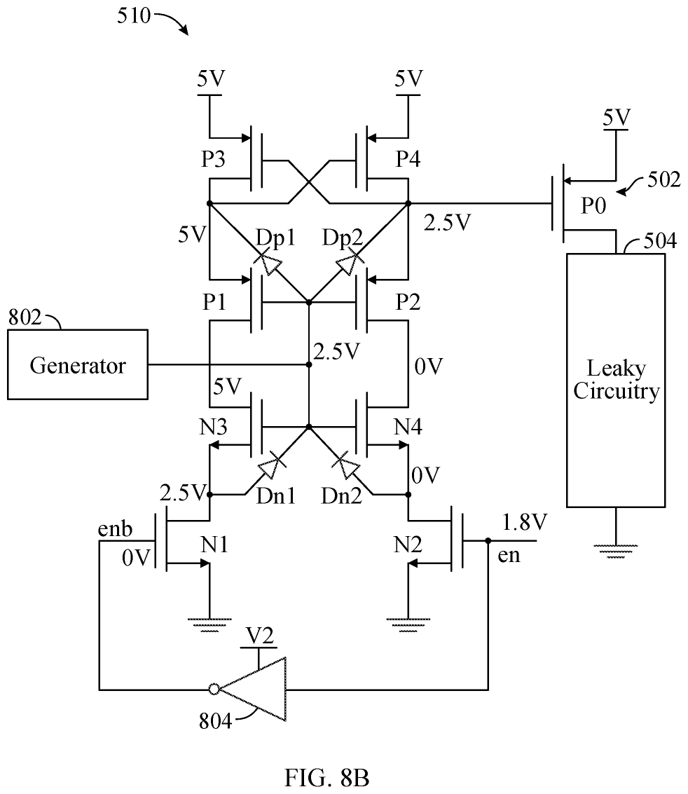

FIG. 8A illustrates an example level shifter 800 with a transistor operating with a negative Vsg with V1 of 5V and V2 of 1.8V. As shown, the level shifter 800 includes PMOS transistors P1, P2, P3, and P4, NMOS transistors N1 and N2, and an inverter 804 with V2 supply. Sources of PMOS transistors P3 and P4 are coupled to a voltage rail (e.g., voltage rail V1 described with respect to FIGS. 5 and 6), providing a 5 V supply. The transistors P3 and P4 may be cross-coupled. For example, a gate of transistor P3 may be coupled to a drain of transistor P4, and a gate of transistor P4 may be coupled to a drain of transistor P3. The drains of transistor P4 is coupled to a gate of a PMOS transistor P0 used to implement the head switch 502.

In some aspects, transistors P1 and P2 may be coupled in cascode with transistors P3 and P4, respectively. For example, a source of transistor P1 may be coupled to the drain of transistor P3, and a source of transistor P2 may be coupled to the drain of transistor P4. A voltage generator 802 may be used to generate a voltage at gates of PMOS transistors P1 and P2. For instance, the generator 802 may provide a 2.5 V signal to the gates of transistors P1 and P2.

A drain of transistor P1 may be coupled to a drain of an n-type metal-oxide-semiconductor (NMOS) transistor N1, and a drain of transistor P2 may be coupled to a drain of NMOS transistor N2. The sources of the transistors N1 and N2 may be coupled to a reference potential node (e.g., electrical ground). Transistors N1 and N2 may be input transistors. For example, a gate of transistor N2 may receive an input signal (e.g., an enable signal labeled “en”), and a gate of transistor N1 may receive a complementary input signal (e.g., a complementary enable signal labeled “enb”). When the level shifter 800 is enabled to close the head switch 502, the gate of transistor N2 may be provided a logic high input (e.g., 1.8 V input). The gate of transistor N2 may be coupled to the gate of transistor N1 through an inverter 804, as shown. Thus, the gate of transistor N1 may receive a logic low input (e.g., 0 V input). The transistor N2 may be turned on, electrically coupling the reference potential node (electric ground) to the drain of transistor P2.

As described, the generator 802 may provide a 2.5 V signal to the gates of transistors P1 and P2. Moreover, the transistor P2 may operate with a negative Vsg (e.g., −2.5 V), resulting in the source of transistor P2 being at 0V. Thus, the gates of transistor P0 and transistor P3 may be at 0V. As a result, the Vsg of transistor P0 and transistor P3 may be 5 V, which may exceed the 3 V Vsg capability of transistors P0 and P3. With transistor P3 being tuned on, the drain of transistor P3 (and the drain of transistor P1) may be at 5 V. Thus, the drain-to-gate voltage (Vdg) of transistor N1 may be at 5 V which may also exceed the Vdg capability of transistor N1.

FIG. 8B illustrates an example level shifter 510 implemented with diodes so that transistors of the level shifter 510 do not operate with negative Vsg, in accordance with certain aspects of the present disclosure. As shown, an NMOS transistor N3 may be coupled between transistor N1 and transistor P1, and an NMOS transistor N4 may be coupled between transistor N2 and transistor P2. The transistors N3 and N4 may be coupled in cascode with transistors N1 and N2, respectively. A source of transistor N3 may be coupled to the drain of transistor N1, and a drain of transistor N3 may be coupled to the drain of transistor P1. A source of transistor N4 may be coupled to the drain of transistor N2, and a drain of transistor N4 may be coupled to the drain of transistor P2.

A diode Dp1 may be coupled between the gate and the source of transistor P1, and a diode Dp2 may be coupled between the gate and the source of transistor P2 (anodes of diodes Dp1 and Dp2 being coupled to the gates of transistors P1 and P2). A diode Dn1 may be coupled between the source and the gate of transistor N3, and a diode Dn2 may be coupled between the source and the gate of transistor N4 (cathodes of diodes Dn1 and Dn2 being coupled to the gates of transistors N3 and N4). Due to diodes Dp1 and Dp2, transistors P1 and P2 do not operate at the negative Vsg bias point. For instance, diode Dp2 (or Dp1) may clamp the voltage difference between the source and gate of transistor P2 (or P1) so that the transistor P2 (or P1) does not operate at the negative Vsg bias point (e.g., −2.5 V). In other words, if the Vsg of transistor P1 (or P2) drops below a voltage drop (e.g., 0.7 V) of diode Dp1 (or Dp2), diode Dp1 (or Dp2) begins to conduct so that the Vsg of transistor P1 (or P2) does not operate at the negative Vsg.

Similar to PMOS transistors, an NMOS transistor may have two bi-stable bias points. For example, without diodes Dn1 and Dn2, transistor N3 (or N4) may operate at a negative gate-to-source voltage (Vgs). Thus, transistor Dn1 (or Dn2) may clamp the voltage difference between the gate and source of transistor N3 (or N4) so that the transistor N3 (or N4) does not operate at the negative Vgs bias point (e.g., −2.5 V). In other words, if the Vgs of transistor N3 (or N4) drops below a voltage drop (e.g., 0.7 V) of diode Dn1 (or Dn2), diode Dn1 (or Dn2) begins to conduct so that the Vgs of transistor N3 (or N4) does not operate at the negative Vgs. In this manner, the transistors of the level shifter 510 and the transistor P0 used to implement the head switch 502 operate within respective Vgs and Vsg capabilities.

As shown, the generator 802 may generate a voltage signal (e.g., a 2.5 V signal) at the gates of transistors P1, P2, N3, and N4. The voltage generated by generator 802 may be equal to the voltage at rail V1 (e.g., 5 V) minus a voltage offset (e.g., 2.5 V, also referred to as a “voltage threshold”). The voltage offset may be less than the Vsg and Vgs capabilities of the PMOS and NMOS transistors (e.g., PMOS and NMOS transistors of level shifter 510 and PMOS transistor P0). For instance, where transistor P0 is unable to handle a Vsg greater than 3 V, the voltage offset may be less than 3 V (e.g., 2.5 V). Thus, for a 5 V voltage rail, the generator 802 may provide a 2.5 V signal (e.g., 5 V minus 2.5 V) to the gates of transistors P1, P2, N3, and N4.

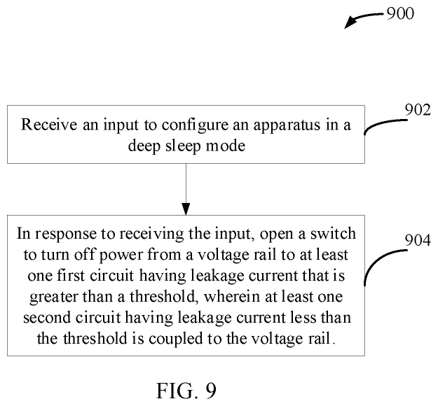

FIG. 9 is a flow diagram illustrating example operations 900 for power management, in accordance with certain aspects of the present disclosure. The operations 900 may be performed, for example, by power management circuitry, such as power management circuitry 500 or 600.

At block 902, the power management circuitry may receive (e.g., via logic 508) an input to configure an apparatus in a deep sleep mode.

At block 904, the power management circuitry may open a switch to turn off power from a voltage rail to at least one first circuit (e.g., leaky circuitry 504) having a leakage current that is greater than a threshold. In some aspects, the at least one first circuit may include an LDO regulator. The switch may include a head switch coupled between the voltage rail and the at least one first circuit. In some aspects, receiving the input may include receiving a digital combination (e.g., a binary input of 0000) indicating to place the at least one first circuit in the deep sleep mode. In some aspects, at least one second circuit (e.g., low leakage circuitry 506) having a leakage current less than the threshold may be coupled (e.g., directly coupled) to the voltage rail. The at least one second circuit may include a PA.

In some aspects, the power management circuitry may store status information associated with the at least one first circuit in one or more registers (e.g., one or more registers 604) prior to opening the switch. The power management circuitry may activate the at least one first circuit (e.g., an LDO regulator) using the status information.

In some aspects, the power management circuitry may also configure the apparatus in a sleep mode. During the sleep mode, the at least one first circuit may be configured in a low-power mode.

In some aspects, the power management circuitry may control the switch based on an output signal from the logic using a level shifter. The level shifter may include a pair of cross-coupled transistors (e.g., transistors P3 and P4 shown in FIG. 8B). For example, a first transistor of the pair of cross-coupled transistors may have a gate coupled to a drain of a second transistor of the pair of cross-coupled transistors, and the second transistor of the pair of cross-coupled transistors may have a gate coupled to a drain of the first transistor of the pair of cross-coupled transistors.

The level shifter may also include a first pair of cascode transistors (e.g., transistors P1 and P2 shown in FIG. 8B) coupled in cascode to the pair of cross-coupled transistors, respectively. In some aspects, a first diode (e.g., diode Dp1) may be coupled between a gate and a source of a first transistor of the first pair of cascode transistors, and a second diode (e.g., diode Dp2) may be coupled between a gate and a source of a second transistor of the first pair of cascode transistors. The level shifter may also include a pair of input transistors (e.g., transistors N1 and N2) having drains coupled to drains of the first pair of cascode transistors, respectively. In some aspects, anodes of the first diode and the second diode are coupled to the gates of the first transistor and the second transistor, and cathodes of the first diode and the second diode are coupled to the sources of the first transistor and the second transistor, respectively.

In some aspects, gates of the pair of input transistors are coupled to respective inputs of the level shifter, where the respective inputs of the level shifter are coupled to an output of the logic. In some aspects, a second pair of cascode transistors (e.g., transistors N3 and N4) may be coupled in cascode with the pair of input transistors, respectively. A third diode (e.g., diode Dn1) may be coupled between a gate and a source of a first transistor of the second pair of cascode transistors, and a fourth diode (e.g., diode Dn2) may be coupled between a gate and a source of a second transistor of the second pair of cascode transistors.

In some aspects, a drain of a first transistor (e.g., transistor P4) of the pair of cross-coupled transistors may be coupled to a control input of the switch (e.g., a gate of transistor P0). In some aspects, the level shifter may also include a voltage generator (e.g., generator 802) having an output coupled to gates of the first pair of cascode transistors. In some aspects, sources of the pair of cross-coupled transistors may be configured to receive a supply voltage (e.g., from voltage rail V1), and the voltage generator may provide a voltage to the gates of the first pair of cascode transistors, the voltage being based on the supply voltage. The voltage may be equal to the supply voltage minus a voltage threshold. The voltage threshold may be less than or equal to a source-to-gate voltage capability of a transistor used to implement the switch.

Some aspects provide an apparatus for power management. The apparatus generally includes: a low-dropout (LDO) regulator (e.g., LDO regulator 505); a headswitch (e.g., switch 502) coupled between a voltage rail and a power supply node of the LDO regulator; a level shifter (e.g., level shifter 510) configured to control a state of the headswitch; and logic (e.g., logic 508) coupled to the level shifter and configured to control the level shifter based on a first sleep state (e.g., sleep mode 404), a second sleep state (e.g., deep sleep mode 400), and a third state (e.g., active mode 406) of the apparatus.

### Example Aspects

Aspect 1: An apparatus for power management, comprising: a switch; and logic configured to: receive an input to configure the apparatus in a deep sleep mode; and in response to the received input, open the switch to turn off power from a voltage rail to at least one first circuit having a leakage current that is greater than a threshold, wherein at least one second circuit having a leakage current less than the threshold is coupled to the voltage rail.

Aspect 2: The apparatus of Aspect 1, wherein the at least one first circuit comprises a low dropout (LDO) regulator.

Aspect 3: The apparatus of Aspect 1 or 2, wherein the at least one second circuit comprises a power amplifier (PA).

Aspect 4: The apparatus according to any of Aspects 1-3, wherein the switch comprises a head switch coupled between the voltage rail and the at least one first circuit.

Aspect 5: The apparatus according to any of Aspects 1-4, wherein the logic is further configured to: receive another input to configure the apparatus to exit the deep sleep mode; and in response to the other input, close the switch and activate the at least one first circuit.

Aspect 6: The apparatus of Aspect 5, wherein the logic is further configured to store status information associated with the at least one first circuit in one or more registers prior to opening the switch, wherein the at least one first circuit is activated using the status information.

Aspect 7: The apparatus of Aspect 6, wherein the at least one first circuit includes a low dropout (LDO) regulator.

Aspect 8: The apparatus according to any of Aspects 1-7, wherein, to receive the input, the logic is configured to receive a digital combination indicating to place the at least one first circuit in the deep sleep mode.

Aspect 9: The apparatus according to any of Aspects 1-8, wherein the logic is further configured to configure the apparatus in a sleep mode during which the at least one first circuit is configured in a low-power mode.

Aspect 10: The apparatus according to any of Aspects 1-9, further comprising a level shifter configured to control the switch based on an output signal from the logic.

Aspect 11: The apparatus of Aspect 10, wherein the level shifter comprises: a pair of cross-coupled transistors; a first pair of cascode transistors coupled in cascode to the pair of cross-coupled transistors, respectively; a first diode coupled between a gate and a source of a first transistor of the first pair of cascode transistors; and a second diode coupled between a gate and a source of a second transistor of the first pair of cascode transistors.

Aspect 12: The apparatus of Aspect 11, further comprising: a pair of input transistors having drains coupled to drains of the first pair of cascode transistors, respectively.

Aspect 13: The apparatus of Aspect 12, wherein gates of the pair of input transistors are coupled to respective inputs of the level shifter, and wherein the respective inputs of the level shifter are coupled to an output of the logic.

Aspect 14: The apparatus of Aspect 12 or 13, wherein the level shifter further comprises: a second pair of cascode transistors coupled in cascode with the pair of input transistors, respectively; and a third diode coupled between a gate and a source of a first transistor of the second pair of cascode transistors; and a fourth diode coupled between a gate and a source of a second transistor of the second pair of cascode transistors.

Aspect 15: The apparatus according to any of Aspects 11-14, wherein: anodes of the first diode and the second diode are coupled to the gates of the first transistor and the second transistor; and cathodes of the first diode and the second diode are coupled to the sources of the first transistor and the second transistor, respectively.

Aspect 16: The apparatus according to any of Aspects 11-15, wherein a drain of a transistor of the pair of cross-coupled transistors is coupled to a control input of the switch.

Aspect 17: The apparatus according to any of Aspects 11-16, wherein: a first transistor of the pair of cross-coupled transistors has a gate coupled to a drain of a second transistor of the pair of cross-coupled transistors; and the second transistor of the pair of cross-coupled transistors has a gate coupled to a drain of the first transistor of the pair of cross-coupled transistors.

Aspect 18: The apparatus according to any of Aspects 11-17, wherein the level shifter further comprises a voltage generator having an output coupled to gates of the first pair of cascode transistors.

Aspect 19: The apparatus of Aspect 18, wherein: sources of the pair of cross-coupled transistors are configured to receive a supply voltage; and the voltage generator is configured to provide a voltage to the gates of the first pair of cascode transistors, the voltage being based on the supply voltage.

Aspect 20: The apparatus of Aspect 19, wherein the voltage is equal to the supply voltage minus a voltage threshold, wherein the voltage threshold is less than or equal to a source-to-gate voltage capability of a transistor used to implement the switch.

Aspect 21: A level shifter comprising: a pair of cross-coupled transistors; a first pair of cascode transistors coupled in cascode to the pair of cross-coupled transistors, respectively; a first diode coupled between a gate and a source of a first transistor of the first pair of cascode transistors; a second diode coupled between a gate and a source of a second transistor of the first pair of cascode transistors; and a pair of input transistors having drains coupled to drains of the first pair of cascode transistors, respectively.

Aspect 22: The level shifter of Aspect 21, wherein: anodes of the first diode and the second diode are coupled to the gates of the first transistor and the second transistor; and cathodes of the first diode and the second diode are coupled to the sources of the first transistor and the second transistor, respectively.

Aspect 23: The level shifter of Aspect 21 or 22, wherein gates of the pair of input transistors are coupled to respective inputs of the level shifter.

Aspect 24: The level shifter according to any of Aspects 21-23, further comprising: a second pair of cascode transistors coupled in cascode with the pair of input transistors, respectively; and a third diode coupled between a gate and a source of a first transistor of the second pair of cascode transistors; and a fourth diode coupled between a gate and a source of a second transistor of the second pair of cascode transistors.

Aspect 25: The level shifter according to any of Aspects 21-24, wherein: a first transistor of the pair of cross-coupled transistors has a gate coupled to a drain of a second transistor of the pair of cross-coupled transistors; and the second transistor of the pair of cross-coupled transistors has a gate coupled to a drain of the first transistor of the pair of cross-coupled transistors.

Aspect 26: The level shifter according to any of Aspects 21-25, further comprising a voltage generator having an output coupled to gates of the first pair of cascode transistors.

Aspect 27: The level shifter of Aspect 26, wherein: sources of the pair of cross-coupled transistors are configured to receive a supply voltage; and the voltage generator is configured to provide a voltage to the gates of the first pair of cascode transistors, the voltage being based on the supply voltage.

Aspect 28: The level shifter of Aspect 27, wherein the voltage is equal to the supply voltage minus a voltage threshold, wherein the voltage threshold is less than or equal to a source to source-to-gate voltage capability of at least one of the first pair of cross-coupled transistors or the pair of input transistors.

Aspect 29: A method for power management, comprising: receiving an input to configure an apparatus in a deep sleep mode; and in response to receiving the input, opening a switch to turn off power from a voltage rail to at least one first circuit having a leakage current that is greater than a threshold, wherein at least one second circuit having a leakage current less than the threshold is coupled to the voltage rail.

Aspect 30: An apparatus for power management, comprising: a low-dropout (LDO) regulator; a headswitch coupled between a voltage rail and a power supply node of the LDO regulator; a level shifter configured to control a state of the headswitch; and logic coupled to the level shifter and configured to control the level shifter based on a first sleep state, a second sleep state, and a third state of the apparatus.

### ADDITIONAL CONSIDERATIONS

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another-even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112 (f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. An apparatus for power management, comprising:
a switch; and
logic configured to:
receive an input to configure the apparatus in a deep sleep mode; and
in response to the received input, open the switch to turn off power from a voltage rail to at least one first circuit having a leakage current that is greater than a threshold, wherein at least one second circuit having a leakage current less than the threshold is coupled to the voltage rail.

2. The apparatus of claim 1, wherein the at least one first circuit comprises a low dropout (LDO) regulator.

3. The apparatus of claim 1, wherein the at least one second circuit comprises a power amplifier (PA).

4. The apparatus of claim 1, wherein the switch comprises a head switch coupled between the voltage rail and the at least one first circuit.

5. The apparatus of claim 1, wherein the logic is further configured to:
receive another input to configure the apparatus to exit the deep sleep mode; and
in response to the other input, close the switch and activate the at least one first circuit.

6. The apparatus of claim 5, wherein the logic is further configured to store status information associated with the at least one first circuit in one or more registers prior to opening the switch, wherein the at least one first circuit is activated using the status information.

7. The apparatus of claim 6, wherein the at least one first circuit includes a low dropout (LDO) regulator.

8. The apparatus of claim 1, wherein, to receive the input, the logic is configured to receive a digital combination indicating to place the at least one first circuit in the deep sleep mode.

9. The apparatus of claim 1, wherein the logic is further configured to configure the apparatus in a sleep mode during which the at least one first circuit is configured in a low-power mode.

10. The apparatus of claim 1, further comprising a level shifter configured to control the switch based on an output signal from the logic.

11. The apparatus of claim 10, wherein the level shifter comprises:
a pair of cross-coupled transistors;
a first pair of cascode transistors coupled in cascode to the pair of cross-coupled transistors, respectively;
a first diode coupled between a gate and a source of a first transistor of the first pair of cascode transistors; and
a second diode coupled between a gate and a source of a second transistor of the first pair of cascode transistors.

12. The apparatus of claim 11, further comprising:
a pair of input transistors having drains coupled to drains of the first pair of cascode transistors, respectively.

13. The apparatus of claim 12, wherein gates of the pair of input transistors are coupled to respective inputs of the level shifter, and wherein the respective inputs of the level shifter are coupled to an output of the logic.

14. The apparatus of claim 12, wherein the level shifter further comprises:
a second pair of cascode transistors coupled in cascode with the pair of input transistors, respectively; and
a third diode coupled between a gate and a source of a first transistor of the second pair of cascode transistors; and
a fourth diode coupled between a gate and a source of a second transistor of the second pair of cascode transistors.

15. The apparatus of claim 11, wherein:
anodes of the first diode and the second diode are coupled to the gates of the first transistor and the second transistor; and
cathodes of the first diode and the second diode are coupled to the sources of the first transistor and the second transistor, respectively.

16. The apparatus of claim 11, wherein a drain of a transistor of the pair of cross-coupled transistors is coupled to a control input of the switch.

17. The apparatus of claim 11, wherein:
a first transistor of the pair of cross-coupled transistors has a gate coupled to a drain of a second transistor of the pair of cross-coupled transistors; and
the second transistor of the pair of cross-coupled transistors has a gate coupled to a drain of the first transistor of the pair of cross-coupled transistors.

18. The apparatus of claim 11, wherein the level shifter further comprises a voltage generator having an output coupled to gates of the first pair of cascode transistors.

19. The apparatus of claim 18, wherein:
sources of the pair of cross-coupled transistors are configured to receive a supply voltage; and
the voltage generator is configured to provide a voltage to the gates of the first pair of cascode transistors, the voltage being based on the supply voltage.

20. The apparatus of claim 19, wherein the voltage is equal to the supply voltage minus a voltage threshold, wherein the voltage threshold is less than or equal to a source-to-gate voltage capability of a transistor used to implement the switch.

21. A level shifter comprising:
a pair of cross-coupled transistors;
a first pair of cascode transistors coupled in cascode to the pair of cross-coupled transistors, respectively;
a first diode coupled between a gate and a source of a first transistor of the first pair of cascode transistors;
a second diode coupled between a gate and a source of a second transistor of the first pair of cascode transistors; and
a pair of input transistors having drains coupled to drains of the first pair of cascode transistors, respectively.

22. The level shifter of claim 21, wherein:
anodes of the first diode and the second diode are coupled to the gates of the first transistor and the second transistor; and
cathodes of the first diode and the second diode are coupled to the sources of the first transistor and the second transistor, respectively.

23. The level shifter of claim 21, wherein gates of the pair of input transistors are coupled to respective inputs of the level shifter.

24. The level shifter of claim 21, further comprising:
a second pair of cascode transistors coupled in cascode with the pair of input transistors, respectively; and
a third diode coupled between a gate and a source of a first transistor of the second pair of cascode transistors; and
a fourth diode coupled between a gate and a source of a second transistor of the second pair of cascode transistors.

25. The level shifter of claim 21, wherein:
a first transistor of the pair of cross-coupled transistors has a gate coupled to a drain of a second transistor of the pair of cross-coupled transistors; and
the second transistor of the pair of cross-coupled transistors has a gate coupled to a drain of the first transistor of the pair of cross-coupled transistors.

26. The level shifter of claim 21, further comprising a voltage generator having an output coupled to gates of the first pair of cascode transistors.

27. The level shifter of claim 26, wherein:
sources of the pair of cross-coupled transistors are configured to receive a supply voltage; and
the voltage generator is configured to provide a voltage to the gates of the first pair of cascode transistors, the voltage being based on the supply voltage.

28. The level shifter of claim 27, wherein the voltage is equal to the supply voltage minus a voltage threshold, wherein the voltage threshold is less than or equal to a source to source-to-gate voltage capability of at least one of the first pair of cross-coupled transistors or the pair of input transistors.

29. A method for power management, comprising:
receiving an input to configure an apparatus in a deep sleep mode; and
in response to receiving the input, opening a switch to turn off power from a voltage rail to at least one first circuit having a leakage current that is greater than a threshold, wherein at least one second circuit having a leakage current less than the threshold is coupled to the voltage rail.

30. An apparatus for power management, comprising:
a low-dropout (LDO) regulator;
a headswitch coupled between a voltage rail and a power supply node of the LDO regulator;
a level shifter configured to control a state of the headswitch; and
logic coupled to the level shifter and configured to control the level shifter based on a first sleep state, a second sleep state, and a third state of the apparatus.
